(19) United States
(12) Patent Application Publication
(10) Pub. No.: US 2025/0255123 A1
(43) Pub. Date: Aug. 7, 2025

(54) DISPLAY DEVICE

(71) Applicant: LG Display Co., Ltd., Seoul (KR)

(72) Inventors: Yein HONG, Goyang-si (KR); JunYoung KWON, Goyang-si (KR)

(73) Assignee: LG Display Co., Ltd., Seoul (KR)

(21) Appl. No.: 18/919,164

(22) Filed: Oct. 17, 2024

(30) Foreign Application Priority Data
Feb. 2, 2024 (KR) 10-2024-0016795

(51) Int. Cl. H10K 59/131; H10K 59/122; H10K 59/80; H10K 77/10

(52) U.S. Cl. CPC H10K 59/131; H10K 59/122; H10K 59/80518; H10K 59/874; H10K 77/111

(57) ABSTRACT

A display device can include a substrate having a display area and a non-display area, a planarization layer disposed on the substrate, a first power line disposed on the substrate in the non-display area, a second power line disposed on the first power line, first and second dams disposed on the first power line, a first organic pattern configured to connect the planarization layer and the first dam and disposed on the second power line, a second organic pattern configured to connect the first dam and the second dam and disposed on the second power line, and a third power line disposed on the planarization layer, the first dam, and the first organic pattern. The third power line is connected to the second power line, and is disposed along the first dam.

### CROSS-REFERENCE TO RELATED APPLICATIONS

This application claims priority to Korean Patent Application No. 10-2024-0016795 filed on Feb. 2, 2024, in the Korean Intellectual Property Office, the entire contents of which is hereby expressly incorporated by reference into the present application.

### BACKGROUND

### Field

The present disclosure relates to a display device, and more particularly, to a display device capable of improving reliability by inhibiting moisture from penetrating into a display area of the display device.

### Discussion of the Related Art

Display devices, which visually display electrical information signals, are being rapidly developed in accordance with the progress made in the information era. Various studies are being continuously conducted to develop a variety of display devices which are thin and lightweight, consume low power, and have improved performance.

As the representative display devices, there can be a liquid crystal display device (LCD), a field emission display device (FED), an electrowetting display device (EWD), an organic light-emitting display device (OLED), and the like.

An electroluminescent display device such as an organic light-emitting display device is a display device that autonomously emits light. Unlike a liquid crystal display device, the electroluminescent display device does not require a separate light source and thus can be manufactured as a lightweight, thin display device.

In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY OF THE DISCLOSURE

An object to be achieved by aspects of the present disclosure is to provide a display device capable of inhibiting moisture from penetrating into a display area of the display device.

Another object to be achieved by aspects of the present disclosure is to provide a display device capable of suppressing or preventing a dark spot defect which can be caused by silver (Ag) residue in a non-display area of the display device.

Another object to be achieved by aspects of the present disclosure is to provide a display device which can address the limitations and disadvantages of the related art.

Objects of the present disclosure are not limited to the above-mentioned objects, and other objects, which are not mentioned above, can be clearly understood by those skilled in the art from the following descriptions.

A display device according to an embodiment of the present disclosure includes a substrate having a display area in which a plurality of pixels is defined, and a non-display area configured to surround the display area, a planarization layer disposed on the substrate in the display area, a first power line disposed on the substrate in the non-display area, a second power line disposed on the first power line and connected to the first power line in the non-display area, first and second dams disposed on the first power line in the non-display area, the first dam being configured to surround the display area, and the second dam being positioned outward of the first dam, a first organic pattern configured to connect the planarization layer and the first dam and disposed on the second power line, a second organic pattern configured to connect the first dam and the second dam and disposed on the second power line, and a third power line disposed on the planarization layer, the first dam, and the first organic pattern, connected to the second power line, and disposed along the first dam.

Other detailed matters of the example embodiments are included in the detailed description and the drawings.

In the display device according to the embodiment of the present disclosure, the third power line is disposed on the first dam and the first organic pattern, and a propagation route of a crack occurring in the non-display area is blocked, such that the reliability of the display device can be improved.

In the display device according to the embodiment of the present disclosure, the third power line is disposed on the first dam and the first organic pattern, and the third power line is extended and disposed along the first dam, such that one end of the third power line is not disposed in the area that overlaps the first organic pattern. Therefore, a process of patterning an organic layer to cover one end of the third power line is not performed, which can suppress or prevent a problem of presence of a silver (Ag) residue which can be caused by organic layer patterning.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic top plan view of a display device according to an embodiment of the present disclosure;

FIG. 2 is a view schematically illustrating a circuit configuration of a subpixel of the display device according to the embodiment of the present disclosure;

FIG. 3 is a view illustrating in detail a circuit configuration of the subpixel according to the embodiment of the present disclosure;

FIG. 4 is a cross-sectional view taken along line IV-IV′ in FIG. 1;

FIG. 5 is a cross-sectional view taken along line V-V′ in FIG. 1;

FIG. 6 is an enlarged top plan view of area A in FIG. 1;

FIGS. 7A to 7F are layout views for explaining a layered structure in FIG. 6 according to an example of the present disclosure; and

FIG. 8 is a cross-sectional view taken along line VIII-VIII′ in FIG. 6.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to the accompanying drawings. All the components of each display device according to all embodiments of the present disclosure are operatively coupled and configured.

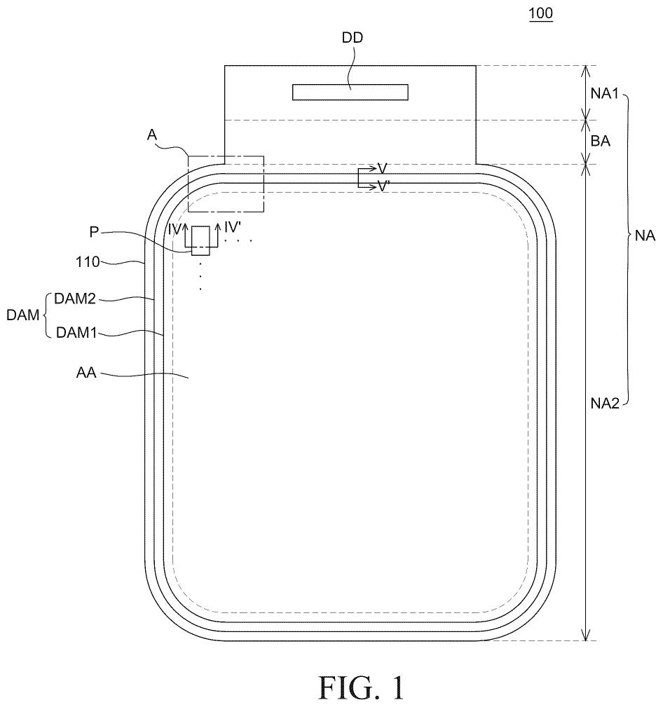

FIG. 1 is a schematic top plan view of a display device according to an embodiment of the present disclosure. For convenience of description, FIG. 1 illustrates a substrate 110, a data driver DD, a first dam DAM1, and a second dam DAM2 among various constituent elements of a display device 100.

With reference to FIG. 1, the substrate 110 includes a display area AA (or active area) and a non-display area NA (or non-active area).

The substrate 110 is a base member for supporting various types of components of the display device 100 and can be made of an insulating material. For example, the substrate 110 can be made of a plastic material such as glass or polyimide.

The display area AA is an area in which images are displayed. A plurality of subpixels, which constitutes a plurality of pixels P, and a driver, which serves to operate the plurality of subpixels, are disposed in the display area AA. The plurality of subpixels are minimum units that constitute the display area AA. Here, n subpixels can constitute each single pixel P, where n can be a real number such as 3 or 4. For example, the subpixels can include a red subpixel, a green subpixel, and a blue subpixel or include a white subpixel, a red subpixel, a green subpixel, and a blue subpixel. The subpixel can have one or more different light-emitting areas depending on luminous properties.

For example, the driver can include various constituent elements such as a power line, a gate line, a data line, a transistor, and a storage capacitor for operating the plurality of pixels P. However, the present disclosure is not limited thereto.

Referring to FIG. 1, the substrate 110 can have variant corner regions. The display area AA can have a shape corresponding to the variant corner regions of the substrate 110. The corners of the substrate 110 and the corners of the display area AA can each have a rounded shape. However, the present disclosure is not limited thereto. The substrate 110 and the display area AA can have various shapes suitable for the design of the electronic apparatus equipped with the display device 100.

The non-display area NA is an area in which no image is displayed. The non-display area NA can surround the display area AA entirely or only in part (s). Various lines, various circuits, and the like for operating the display elements in the display area AA are disposed in the non-display area NA. For example, the data driver DD, a gate driver, a link line, a pad part, and the like can be disposed in the non-display area NA.

The non-display area NA can be an area extending from the display area AA. However, the present disclosure is not limited thereto. The non-display area NA can be an area that surrounds the display area AA.

The non-display area NA includes a first non-display area NA1, a bending area BA, and a second non-display area NA2. The second non-display area NA2 is an area extending from the display area AA. The bending area BA is an area extending from the second non-display area NA2. The bending area BA can be bent. The first non-display area NA1 is an area extending from the bending area BA.

The data driver DD can be disposed in the first non-display area NA1. The pad part having pads connected to various types of signal lines or a PCB can be further disposed in the first non-display area NA1. For example, a power supply pad, a data pad, a gate pad, and the like can be disposed on the pad part.

The data driver DD can be mounted on or connected to a separate PCB and connected to a display panel through the pad part. Alternatively, the data driver DD can be mounted or connected, in the form of a chip-on-panel (COP) between the pad part and the display area AA. The data driver DD includes at least one source drive integrated circuit (IC). The at least one source drive IC is supplied with digital video data and a source timing control signal from a timing controller. The at least one source drive IC generates a data voltage by converting digital video data into a gamma voltage in response to the source timing control signal and supplies the data voltage through the data line in the display area AA.

The bending area BA can be an area in which the substrate 110 is bent. For example, the substrate 110 can be maintained in a flat state without being bent in an area excluding the bending area BA, and the substrate 110 can be configured to be bent in the bending area BA. Therefore, the display device 100 can be bent so that two non-bent areas of the substrate 110, except for the bending area BA of the substrate 110, face each other.

The second non-display area NA2 is an area between the bending area BA and the display area AA. The link lines such as a power link line and a data link line can be disposed in the second non-display area NA2. For example, the second non-display area NA2 serves to transmit a signal, which is outputted from the driver, to the display area AA. In the case in which the substrate 110 includes the variant corner regions, the second non-display area NA2 can have a shape corresponding to the shape of the substrate 110 and the shape of the display area AA.

The gate drivers can be disposed at two opposite sides of the display area AA in the second non-display area NA2 of the non-display area NA. The gate driver can be implemented by a gate-in-panel (GIP) method. However, the present disclosure is not limited thereto.

Meanwhile, a dam DAM can be disposed in the non-display area NA and disposed in a shape that surrounds the display area AA. For example, the dam DAM can include the first dam DAM1 and the second dam DAM2 spaced apart from the first dam DAM1 at a predetermined interval. However, the present disclosure is not limited thereto. The dam DAM can be configured as a single dam or three or more dams.

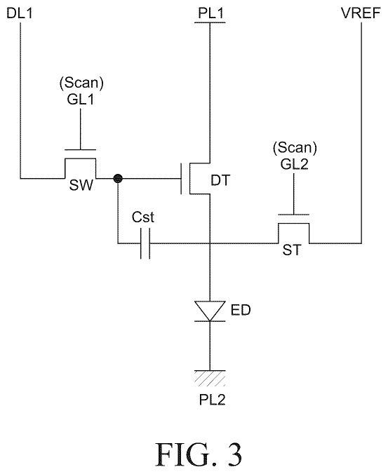

As illustrated in FIG. 1, in case that the substrate 110 includes the bending area BA extending and bent from one side of the non-display area NA, the dam DAM can be disposed between the display area AA and the bending area BA and surround the display area AA. In case that the corner of the display area AA has a round shape, the first dam DAM1 and the second dam DAM2 can also have round shapes. For example, the first dam DAM1 and the second dam DAM2 can each include a first portion extending in a rectilinear direction between the display area AA and the bending area BA, and a second portion extending from the first portion in a curved direction. The dam DAM will be described in more detail with reference to FIG. 3.

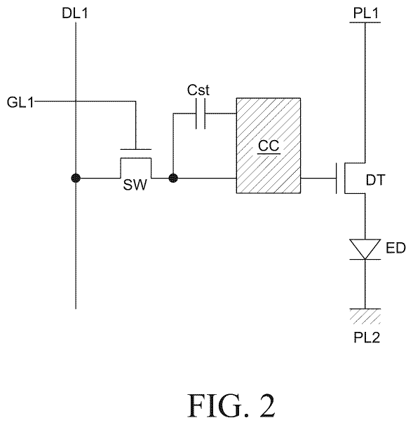

FIG. 2 is a view schematically illustrating a circuit configuration of the subpixel according to the embodiment of the present disclosure. Each subpixel of any display device in the present disclosure can have the subpixel configuration of FIG. 2, FIG. 3 or any other figure herein.

With reference to FIG. 2, one subpixel can include a switching transistor SW, a driving transistor DT, a capacitor Cst, a compensating circuit CC, and an organic light-emitting element OLED.

For example, the switching transistor SW can perform a switching operation so that a data signal supplied through a first data line DL1 is stored, as a data voltage, in the capacitor Cst in response to a scan signal supplied through a first gate line GL1. In addition, for example, the driving transistor DT can operate such that a drive current flows between a first power line PL1 (high-potential voltage) and a second power line PL2 (low-potential voltage) in accordance with the data voltage stored in the capacitor Cst. In addition, the organic light-emitting element OLED can operate to emit light in accordance with a drive current produced by the driving transistor DT.

The compensating circuit CC refers to a circuit added into the subpixel to compensate for a threshold voltage of the driving transistor DT or the like. The compensating circuit CC can include one or more transistors. The compensating circuit CC can have very various configurations depending on an external compensation method. An example of the compensating circuit CC will be described below.

FIG. 3 is a view illustrating in detail a circuit configuration of the subpixel according to the embodiment of the present disclosure.

With reference to FIG. 3, for example, the compensating circuit CC can include a sensing transistor ST and a sensing line VREF (or a reference line).

In this case, the sensing transistor ST can be connected between a drain electrode of the driving transistor DT and a first electrode (hereinafter, referred to as a sensing node) of the organic light-emitting element OLED. The sensing transistor ST can operate to supply an initialization voltage (or a sensing voltage), which is transmitted through the sensing line VREF, to the sensing node of the driving transistor DT or sense a voltage or current of the sensing node of the driving transistor DT or the sensing line VREF.

One of a source electrode and a drain electrode of the switching transistor SW can be connected to the first data line DL1, and the other of the source electrode and the drain electrode of the switching transistor SW can be connected to a gate electrode of the driving transistor DT.

One of a source electrode and a drain electrode of the driving transistor DT can be connected to the first power line PL1, and the other of the source electrode and the drain electrode of the driving transistor DT can be connected to a first electrode, i.e., an anode of the organic light-emitting element OLED.

In addition, a lower electrode of the capacitor Cst can be connected to a gate electrode of the driving transistor DT, and an upper electrode of the capacitor Cst can be connected to the first electrode, i.e., an anode electrode of the organic light-emitting element OLED. The first electrode of the organic light-emitting element OLED can be connected to the other of the source electrode and the drain electrode of the driving transistor DT, and a second electrode, i.e., a cathode electrode of the organic light-emitting element OLED can be connected to the second power line PL2.

In addition, one of a source electrode and a drain electrode of the sensing transistor ST can be connected to the sensing line VREF, and the other of the source electrode and the drain electrode of the sensing transistor ST can be connected to the first electrode, i.e., the sensing node of the organic light-emitting element OLED and the other of the source electrode and the drain electrode of the driving transistor DT.

An operating time of the sensing transistor ST can be similar or identical to or different from that of the switching transistor SW in accordance with an external compensation algorithm (or a configuration of the compensating circuit). For example, a gate electrode of the switching transistor SW can be connected to the first gate line GL1, and a gate electrode of the sensing transistor ST can be connected to a second gate line GL2. In this case, a scan signal Scan can be transmitted to the first gate line GL1, and a sensing signal Sense can be determined to the second gate line GL2. As another example, the first gate line GL1, which is connected to the gate electrode of the switching transistor SW, and the second gate line GL2, which is connected to the gate electrode of the sensing transistor ST can be connected so as to be shared in common.

The sensing line VREF can be connected to the data driver. In this case, in real time, for a non-image display period, or for an N-frame (N is an integer of one or more) period, the data driver can sense a sensing node of the subpixel and create a sensing result.

Meanwhile, the switching transistor SW and the sensing transistor ST can be turned on at the same time. In this case, on the basis of a time division method of the data driver, a sensing operation using the sensing line VREF and a data output operation of outputting the data signal can be separated (distinguished).

In addition, a compensation target according to the sensing result can be a data signal in a digital form, a data signal or gamma in an analog form, and the like. Further, the compensating circuit, which creates a compensation signal (or a compensation voltage) and the like on the basis of the sensing result, can be implemented as the inside of the data driver, the inside of the timing controller, or a separate circuit.

As described above, for example, FIG. 3 illustrates the subpixel with the 3T (transistor) 1C (capacitor) structure including the switching transistor SW, the driving transistor DT, the capacitor Cst, the organic light-emitting element OLED, and the sensing transistor ST. However, in case that the compensating circuit CC is added, the subpixel can have 3T2C, 4T2C, 5T1C, 6T2C, or the like.

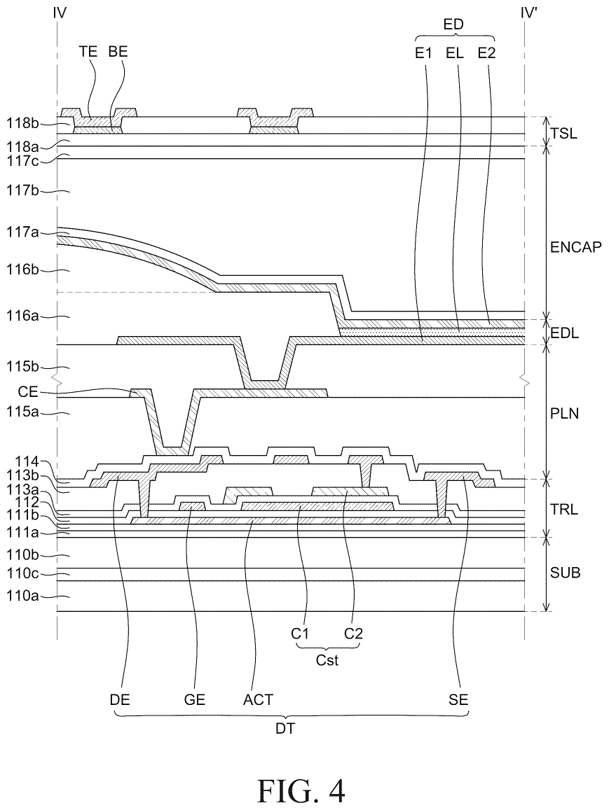

Hereinafter, the cross-sectional structures of the plurality of pixels P disposed in the display area AA of the display device 100 will be described in more detail with reference to FIG. 4.

FIG. 4 is a cross-sectional view taken along line IV-IV′ in FIG. 1.

With reference to FIG. 4, in a subpixel SP disposed in the display area AA, a transistor layer TRL can be disposed above a substrate SUB, and a planarization layer PLN can be disposed above the transistor layer TRL. In addition, a light-emitting element layer EDL can be disposed above the planarization layer PLN, an encapsulation layer ENCAP can be disposed above the light-emitting element layer EDL, and a touch detection layer TSL can be disposed above the encapsulation layer ENCAP.

The substrate SUB is a component for supporting various constituent elements included in the display device 100 and can be made of an insulating material. The substrate SUB can include a first substrate 110a, a second substrate 110b, and an interlayer insulation layer 110c. The interlayer insulation layer 110c can be disposed between the first substrate 110a and the second substrate 110b. As described above, the substrate SUB can include the first substrate 110a, the second substrate 110b, and the interlayer insulation layer 110c, which can suppress or prevent moisture penetration. For example, the first substrate 110a and the second substrate 110b can each be a substrate made of polyimide (PI).

Various types of patterns GE, DE, SE, and ACT for forming a transistor such as the driving transistor DT and various types of insulation layers 111a, 111b, 112, 113a, 113b, and 114 can be disposed on the transistor layer TRL in the display area AA.

Hereinafter, a layered structure of the transistor layer TRL according to aspects of the present disclosure will be described in more detail.

A multi-buffer layer 111a can be disposed on the second substrate 110b, and an active buffer layer 111b can be disposed on the multi-buffer layer 111a.

A light-blocking layer, which serves as a light shield, can be disposed on the multi-buffer layer 111a.

An active layer ACT of the driving transistor DT can be disposed on the active buffer layer 111b.

For example, the active layer ACT can include low-temperature poly-silicon (LTPS). Because a polysilicon material has high mobility (100 cm²/Vs or more), low energy power consumption, and excellent reliability, the polysilicon material can be applied to gate drivers and/or multiplexers (MUX) for driving elements for operating thin-film transistors for display elements. In the display device 100 according to the embodiment of the present disclosure, the polysilicon material can be applied to the active layer of the driving transistor DT. However, the present disclosure is not limited thereto. For example, the polysilicon material can also be applied to an active layer of a switching thin-film transistor in accordance with the characteristics of the display device.

The active layer ACT can include a channel area in which a channel is formed when the driving transistor DT operates, and source and drain areas disposed at two opposite sides of the channel area. The source area means a portion of the active layer ACT connected to a source electrode SE to be described below, and the drain area means a portion of the active layer ACT connected to a drain electrode DE to be described below. The source area and the drain area can be configured by doping the active layer ACT with ions (impurities). The source area and the drain area can be formed by doping the polysilicon material with ions. The channel area can mean a portion in which the polysilicon material remains without being subjected to the ion doping.

For example, the active layer ACT can be made of an oxide semiconductor. The oxide semiconductor material is a material having a larger band gap than a silicon material and has a low off-current because electrons cannot pass through the band gap in an OFF state. Therefore, the thin-film transistor including the active layer ACT made of the oxide semiconductor can be suitable for a switching thin-film transistor that maintains the short ON time and the long OFF time. However, the present disclosure is not limited thereto. The oxide semiconductor material can also be applied to the thin-film driving transistor in accordance with the properties of the display device 100. Further, because the oxide semiconductor material has a low off-current and can decrease a magnitude of an auxiliary capacity, the oxide semiconductor material is suitable for a high-resolution display element. For example, the active layer ACT can be made of a metal oxide. For example, the active layer ACT can be made of various metal oxides such as indium-gallium-zinc-oxide (IGZO), indium-zinc-oxide (IZO), indium-gallium-tin-oxide (IGTO), or indium-gallium-oxide (IGO).

A gate insulation layer 112 can be disposed on the active layer ACT. The gate insulation layer 112 can be made of silicon oxide (SiOx), silicon nitride (SiNx), or a multilayer thereof.

In addition, a gate electrode GE of the driving transistor DT can be disposed on the gate insulation layer 112. The gate electrode GE is disposed on the gate insulation layer 112 and overlaps the active layer ACT. The gate electrode GE can be made of various electrically conductive materials, for example, any one selected from a group consisting of magnesium (Mg), aluminum (Al), nickel (Ni), chromium (Cr), molybdenum (Mo), tungsten (W), gold (Au), titanium (Ti), neodymium (Nd), and copper (Cu) or an alloy thereof. However, the present disclosure is not limited thereto.

A first capacitor electrode C1 of the capacitor Cst can be disposed on the same layer as the gate electrode GE of the driving transistor DT. For example, the first capacitor electrode C1 can be made of any one selected from a group consisting of magnesium (Mg), aluminum (Al), nickel (Ni), chromium (Cr), molybdenum (Mo), tungsten (W), gold (Au), titanium (Ti), neodymium (Nd), and copper (Cu) or an alloy thereof. However, the present disclosure is not limited thereto.

A first interlayer insulation layer 113a can be disposed while covering the gate electrode GE and the first capacitor electrode C1.

A second capacitor electrode C2 can be disposed on the first interlayer insulation layer 113a and overlap the first capacitor electrode C1. The second capacitor electrode C2 can be made of any one selected from a group consisting of magnesium (Mg), aluminum (Al), nickel (Ni), chromium (Cr), molybdenum (Mo), tungsten (W), gold (Au), titanium (Ti), neodymium (Nd), and copper (Cu) or an alloy thereof. However, the present disclosure is not limited thereto.

A second interlayer insulation layer 113b can be disposed on the first interlayer insulation layer 113a and the second capacitor electrode C2.

The source electrode SE and the drain electrode DE of the driving transistor DT can be disposed on the second interlayer insulation layer 113b.

The source electrode SE and the drain electrode DE can be respectively connected to one side and the other side of the active layer ACT through contact holes provided in the second interlayer insulation layer 113b, the first interlayer insulation layer 113a, and the gate insulation layer 112. The source electrode SE and the drain electrode DE can each be made of various electrically conductive materials, for example, any one selected from a group consisting of magnesium (Mg), aluminum (Al), nickel (Ni), chromium (Cr), molybdenum (Mo), tungsten (W), gold (Au), titanium (Ti), neodymium (Nd), and copper (Cu) or an alloy thereof. However, the present disclosure is not limited thereto.

A portion of the active layer ACT, which overlaps the gate electrode GE, is the channel area. One of the source electrode SE and the drain electrode DE is connected to one side of the channel area of the active layer ACT, and the other of the source electrode SE and the drain electrode DE is connected to the other side of the channel area of the active layer ACT.

A passivation layer 114 can be disposed on the source electrode SE and the drain electrode DE. The passivation layer 114 can serve to protect the driving transistor DT and be configured as an inorganic layer, for example, silicon oxide (SiOx), silicon nitride (SiNx), or a multilayer thereof.

The planarization layer PLN can be positioned above the transistor layer TRL.

The planarization layer PLN can include a first planarization layer 115a and a second planarization layer 115b. The planarization layer PLN protects the driving transistor DT and planarizes an upper portion of the driving transistor DT.

The first planarization layer 115a can be disposed on the passivation layer 114.

A connection electrode CE can be disposed on the first planarization layer 115a.

The connection electrode CE can be connected to one of the source electrode SE and the drain electrode DE through a contact hole provided in the first planarization layer 115a.

The second planarization layer 115b can be disposed on the connection electrode CE.

The light-emitting element layer EDL can be positioned above the second planarization layer 115b.

Hereinafter, a layered structure of the light-emitting element layer EDL will be described in detail.

An anode E1 can be disposed on the second planarization layer 115b. In this case, the anode E1 can be electrically connected to the connection electrode CE through a contact hole provided in the second planarization layer 115b. The anode E1 can be made of a metallic material.

In case that the display device 100 is a top-emission type display device in which light emitted from the light-emitting element ED propagates toward an upper side of the substrate SUB on which the light-emitting element ED is disposed, the anode E1 can further include a transparent conductive layer and a reflective layer disposed below the transparent conductive layer. For example, the transparent conductive layer can be made of transparent conductive oxide such as ITO or IZO. For example, the reflective layer can be made of silver (Ag), aluminum (Al), gold (Au), molybdenum (Mo), tungsten (W), chromium (Cr), or an alloy thereof.

A bank 116a can be disposed to cover the anode E1. A portion of the bank 116a, which corresponds to the light-emitting area of the subpixel SP, can be opened. A part of the anode E1 can be exposed through the opened portion (hereinafter, referred to as an open area) of the bank 116a. In this case, the bank 116a can be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

A spacer 116b can be further disposed on the bank 116a. The spacer 116b can suppress or prevent damage to the organic light-emitting element ED that can be which can be caused when a fine metal mask (FMM), which is used to form a light-emitting layer EL of the organic light-emitting element ED, comes into contact directly with the bank 116a or a cathode E2. The spacer 116b can be made of the same material as the bank 116a and made of an insulating material different from the insulating material of the bank 116a. However, the present disclosure is not limited thereto. In addition, the spacer 116b and the bank 116a can be integrated. As the spacer 116b is disposed on the bank 116a, the cathode E2 and the light-emitting layer EL can be disposed to cover the spacer 116b and the bank 116a.

The light-emitting layer EL can be disposed in the open area of the bank 116a. Therefore, the light-emitting layer EL can be disposed on the anode E1 exposed through the open area of the bank 116a.

The cathode E2 can be disposed on the light-emitting layer EL.

The light-emitting element ED can be formed by the anode E1, the light-emitting layer EL, and the cathode E2. The light-emitting layer EL can include a plurality of organic layers.

The encapsulation layer ENCAP can be positioned above the light-emitting element layer EDL.

The encapsulation layer ENCAP can have a single-layer or multilayer structure. For example, the encapsulation layer ENCAP can include a first encapsulation layer 117a, a second encapsulation layer 117b, and a third encapsulation layer 117c.

In this case, the first encapsulation layer 117a and the third encapsulation layer 117c can each be configured as an inorganic layer, and the second encapsulation layer 117b can each be configured as an organic layer. Among the first encapsulation layer 117a, the second encapsulation layer 117b, and the third encapsulation layer 117c, the second encapsulation layer 117b can be thickest and serve as a planarization layer.

The first encapsulation layer 117a can be disposed on the cathode E2 and closest to the light-emitting element ED. The first encapsulation layer 117a can be made of an inorganic insulating material that can be deposited at a low temperature. For example, the first encapsulation layer 117a can be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress or prevent damage to the light-emitting layer EL made of an organic material vulnerable to a high-temperature ambience during a deposition process.

The second encapsulation layer 117b can have a smaller area than the first encapsulation layer 117a. In this case, the second encapsulation layer 117b can be formed to expose two opposite ends of the first encapsulation layer 117a. The second encapsulation layer 117b can serve as a buffer for mitigating stress between the layers. The second encapsulation layer 117b can serve to improve the planarization performance.

For example, the second encapsulation layer 117b can be made of an organic insulating material such as acrylic resin, epoxy resin, polyimide, polyethylene, or silicon oxycarbon (SiOC). For example, the second encapsulation layer 117b can also be formed in an inkjet manner. However, the present disclosure is not limited thereto.

The third encapsulation layer 117c can be formed above the substrate SUB having the second encapsulation layer 117b to cover a top surface and a side surface of each of the second encapsulation layer 117b and the first encapsulation layer 117a. In this case, the third encapsulation layer 117c can minimize or block the penetration of outside moisture or oxygen into the first encapsulation layer 117a and the second encapsulation layer 117b. For example, the third encapsulation layer 117c can be made of an inorganic insulating material such as silicon nitride (SiNx), silicon oxide (SiOx), silicon oxynitride (SiON), or aluminum oxide (Al₂O₃).

The touch sensing layer TSL can be disposed above the encapsulation layer ENCAP.

Specifically, the touch sensing layer TSL can include a touch buffer layer 118a disposed on the encapsulation layer ENCAP, a bridge electrode BE disposed on the touch buffer layer 118a, a touch interlayer insulation layer 118b disposed on the touch buffer layer 118a and the bridge electrode BE, and a touch electrode TE disposed on the touch interlayer insulation layer 118b.

The touch buffer layer 118a can inhibit outside moisture, foreign substances, or a liquid chemical such as a developer or an etching liquid, which is used during a process of manufacturing the touch electrodes formed on the touch buffer layer 118a, from penetrating into the light-emitting element.

The plurality of touch electrodes TE can include a plurality of first touch electrodes extending in a first direction, and a plurality of second touch electrodes extending in a second direction intersecting the first direction.

For example, the plurality of first touch electrodes and the plurality of second touch electrodes can be disposed on the same layer. However, the plurality of second touch electrodes can be disposed to be separated from one another in the area in which the plurality of first touch electrodes and the plurality of second touch electrodes intersect. The plurality of second touch electrodes, which are separated from one another, can be connected by the bridge electrodes BE. The touch interlayer insulation layers 118b can be disposed between the plurality of second touch electrodes and the bridge electrodes BE. The touch buffer layer 118a and the touch interlayer insulation layer 118b can be disposed to remove a level difference at a point, at which the touch electrode TE is disposed, and implement appropriate electrical insulation.

Meanwhile, a polarizing layer can be further disposed on the touch detection layer. The polarizing layer suppresses or minimizes the reflection of external light in the display area DA of the substrate 110. In case that the display device 100 is used outside, external natural light can be introduced and reflected by the reflective layer included in the anode E1 of the light-emitting element ED or reflected by an electrode made of metal and disposed on a lower portion of the light-emitting element ED. The light beams, which are reflected as described above, can inhibit an image on the display device 100 from being visually recognized. The polarizing layer can polarize, in a particular direction, the light introduced from the outside, thereby inhibiting the reflected light from being discharged again to the outside of the display device 100.

A cover glass can be bonded onto the polarizing layer by a bonding layer. The bonding layer can serve to bond the constituent elements of the display device 100. For example, the bonding layer can be formed by using a bonding agent for an optically transparent display such as a pressure-sensitive bonding agent, an optically transparent bonding agent (optical clear adhesive (OCR)), or an optically transparent resin (optical clear resin (OCR)). However, the present disclosure is not limited thereto.

The cover glass can protect the constituent elements of the display device 100 from external impact and suppress or prevent damage such as scratches.

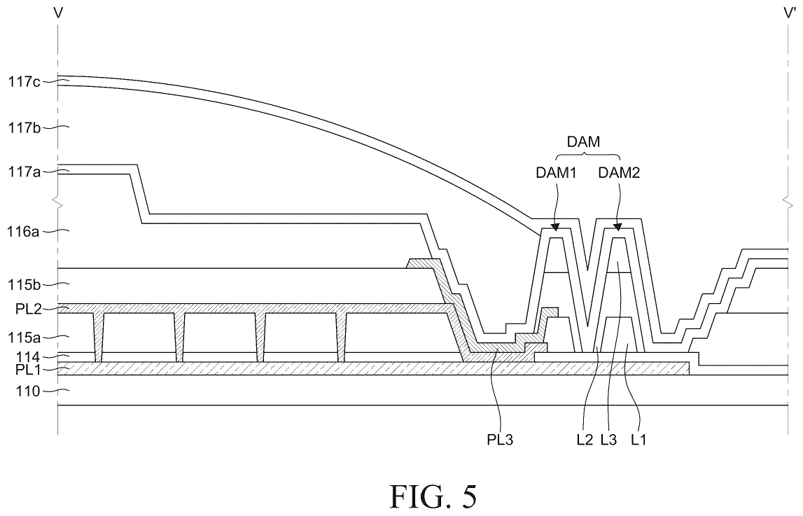

FIG. 5 is a cross-sectional view taken along line V-V′ in FIG. 1. A repeated description of the constituent elements substantially identical to the constituent elements illustrated in FIG. 4 will be omitted or may be briefly provided. The same reference numerals are used for the same components.

The first power line PL1 can be disposed on the substrate 110 in the non-display area NA between the display area AA and the bending area BA. For example, first power Vdd, i.e., a high-potential voltage can be supplied to the pixel P of the display device 100 through the first power line PL1. In this case, the first power line PL1 can be disposed on the same layer and made of the same material as the source electrode SE or the drain electrode DE disposed in the display area AA.

The passivation layer 114 can be disposed to cover the first power line PL1.

The first dam DAM1 and the second dam DAM2 can be disposed on the passivation layer 114 in the non-display area NA and spaced apart from the first planarization layer 115a and the first planarization layer 115a while surrounding the display area AA. For example, the first dam DAM1 and the second dam DAM2 can be disposed to overlap the first power line PL1 without overlapping the first planarization layer 115a.

With reference to FIG. 4 together with FIG. 5, the dam DAM can block a flow of an organic layer, i.e., a flow of the second encapsulation layer 117b that constitutes the encapsulation layer ENCAP. Specifically, the dam DAM can be disposed in a closed-curve shape that surrounds the display area AA in the non-display area NA, and a flow of the second encapsulation layer 117b can be blocked by the dam DAM. For example, the dam DAM can define an area in which the second encapsulation layer 117b is disposed. Therefore, the second encapsulation layer 117b, which is made of an organic insulating material, can inhibit the second encapsulation layer 117b from flowing over in the direction of the non-display area NA and entering the pad part when the second encapsulation layer 117b is applied onto the display area AA.

The dam DAM can have a predetermined height or higher to block a flow of the second encapsulation layer 117b. To this end, the dam DAM can be configured by one or more layers at least made of an organic material. However, the present disclosure is not limited thereto.

The dam DAM can include a first layer L1, and a second layer L2 on the first layer L1. For example, the first layer L1 can be made of the same material as the second planarization layer 115b, and the second layer L2 can be made of the same material as the bank 116a. In this case, it is possible to configure the dam DAM without a process of adding a mask and an increase in costs.

In addition, the dam DAM can further include a third layer L3 on the second layer L2. For example, the third layer L3 can be made of the same material as the spacer 116b. For example, in case that the dam DAM further includes the third layer L3, the height of the dam DAM can increase, which can further improve the effect of blocking a flow of the second encapsulation layer 117b.

A plurality of contact holes for exposing the first power line PL1 can be formed in the passivation layer 114 and the first planarization layer 115a in the non-display area NA between the display area AA and the dam DAM.

The second power line PL2 can be disposed on the first planarization layer 115a in the non-display area NA between the display area AA and the dam DAM. For example, the second power line PL2 can extend to the first dam DAM1 and at least partially overlap the first dam DAM1 in the non-display area NA between the display area AA and the bending area BA. However, the present disclosure is not limited thereto. For example, the second power line PL2 can extend to the second dam DAM2 and at least partially overlap the first dam DAM1 and the second dam DAM2 in the non-display area NA between the display area AA and the bending area BA.

The second power line PL2 can be connected to the first power line PL1 through the plurality of contact holes disposed in the passivation layer 114 and the first planarization layer 115a in the non-display area NA between the display area AA and the bending area BA. For example, second power Vss, i.e., a low-potential voltage can be supplied to the pixel P of the display device 100 through the second power line PL2. For example, the second power line PL2, a third power line PL3, and a second electrode E2 are electrically connected in the area that overlaps a second portion of the dam DAM, such that second power Vss can be applied to the pixel P of the display device 100. In this case, the second power line PL2 can be disposed on the same layer and made of the same material as the connection electrode CE disposed in the display area AA.

The second planarization layer 115b can be disposed on the second power line PL2 to cover the second power line PL2 in the non-display area NA between the display area AA and the bending area BA. Meanwhile, the first layers L1, which are positioned on the same layer as the second planarization layer 115b and spaced apart from the second planarization layer 115b, can be disposed in areas respectively corresponding to the first dam DAM1 and the second dam DAM2. One end of the second power line PL2 can be covered by the first layer L1. Therefore, one end of the second power line PL2 is not exposed to the outside, which can suppress or prevent the occurrence of seam.

The third power line PL3 can be disposed on at least a part of the second planarization layer 115b in the non-display area NA between the display area AA and the bending area BA.

For example, the third power line PL3 can extend to the first dam DAM1 and be disposed to overlap the first dam DAM1 in the non-display area NA between the display area AA and the bending area BA. In this case, the third power line PL3 can be disposed on the same layer and made of the same material as a first electrode E1 disposed in the display area AA.

The bank 116a can be disposed on at least a part of the second planarization layer 115b and at least a part of the third power line PL3 in the non-display area NA between the display area AA and the bending area BA. Meanwhile, the second layer L2, which is positioned on the same layer as the bank 116a and spaced apart from the bank 116a, can be disposed on the first layer L1.

The first encapsulation layer 117a, which extends from the display area AA, can be disposed on the bank 116a, a part of the third power line PL3, the first dam DAM1, and the second dam DAM2 in the non-display area NA between the display area AA and the bending area BA.

The first encapsulation layer 117a, which extends from the display area AA, can be disposed on the first dam DAM1 and the second dam DAM2 in the non-display area NA between the display area AA and the bending area BA.

The second encapsulation layer 117b made of an organic insulating material positioned only inside the first dam DAM1 in the non-display area NA between the display area AA and the bending area BA.

In addition, in the non-display area NA between the display area AA and the bending area BA, the third encapsulation layer 117c, which extends from the display area AA, can be disposed on the substrate 110, on which the second encapsulation layer 117b is disposed, and cover top surfaces and side surfaces of the first and second encapsulation layers 117a and 117b. The third encapsulation layer 117b can minimize the penetration of outside moisture or oxygen into the first encapsulation layer 117a and the second encapsulation layer 117c.

According to the embodiment of the present disclosure, the first dam DAM1 and the second dam DAM2 can suppress or prevent a flow of the second encapsulation layer 117b in the non-display area NA between the display area AA and the bending area BA.

In addition, one end of each of the first power line PL1, the second power line PL2, and the third power line PL3 disposed in the non-display area NA between the display area AA and the bending area BA is not exposed to the outside, which can suppress or prevent the occurrence of seam.

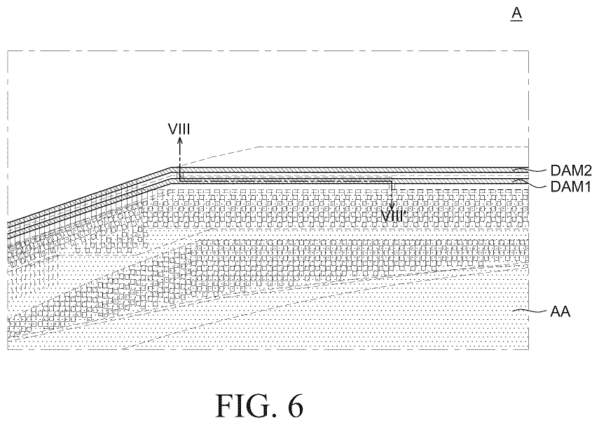

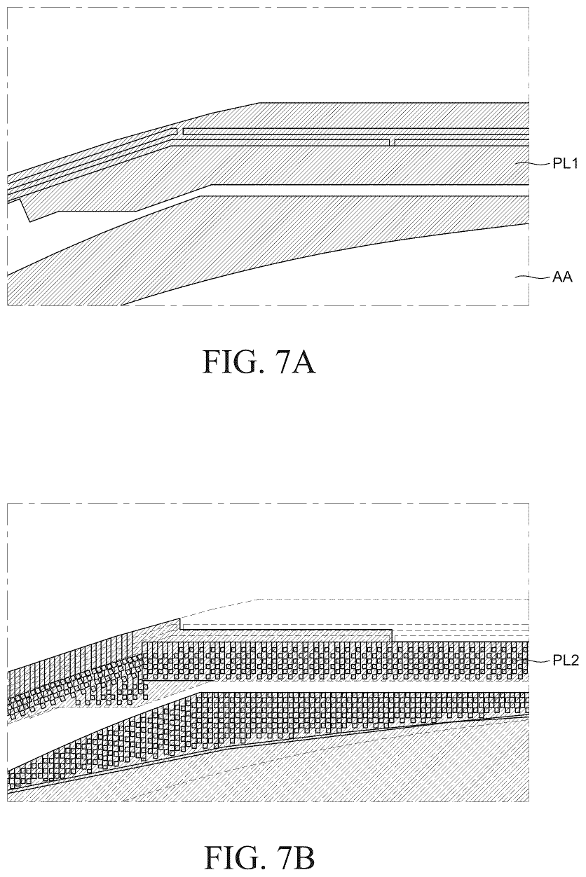

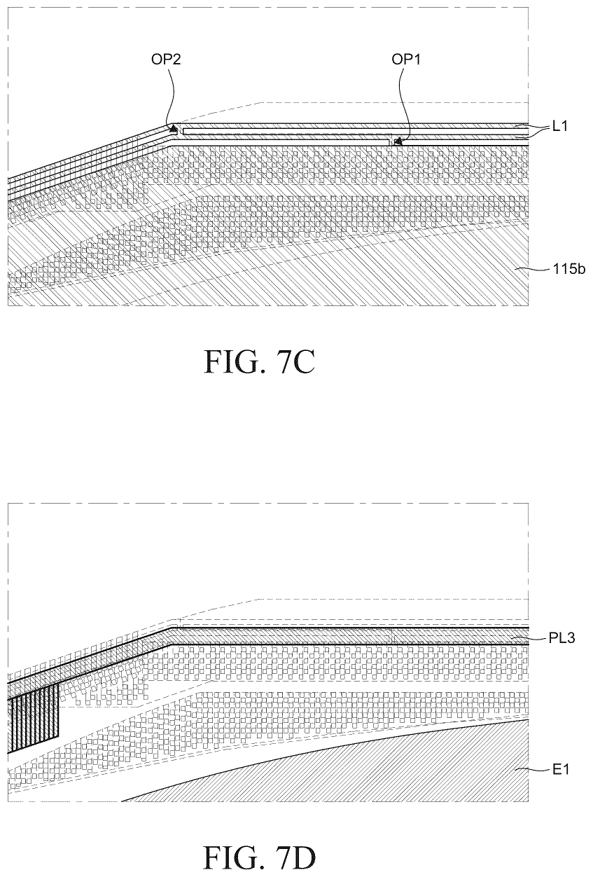

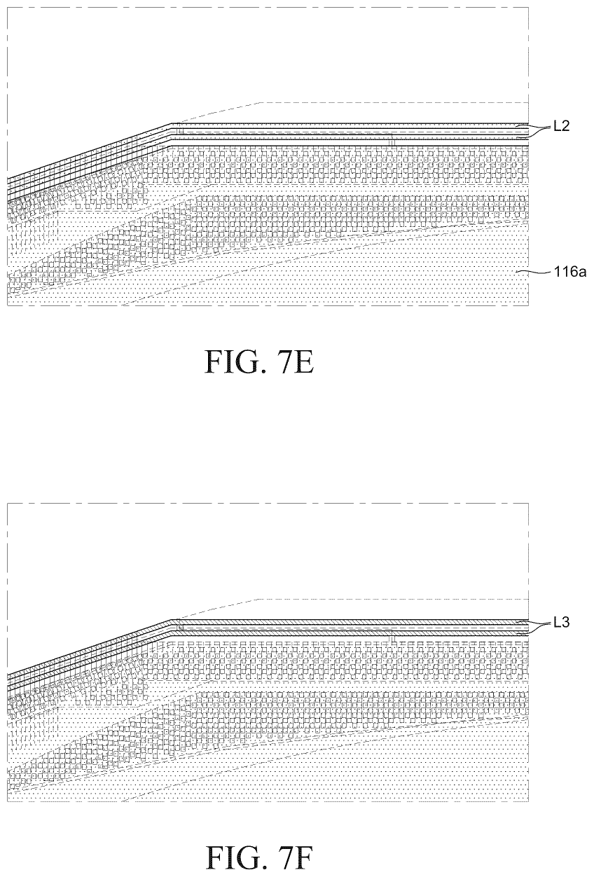

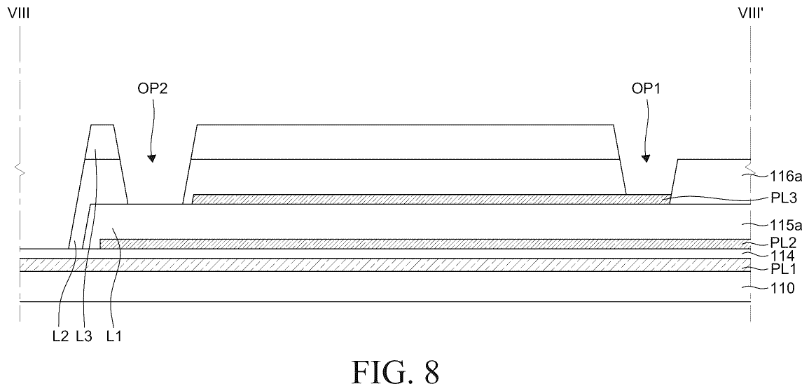

FIG. 6 is an enlarged top plan view of area A in FIG. 1. FIGS. 7A to 7F are layout views for explaining a layered structure in FIG. 6 according to an example of the present disclosure. FIG. 8 is a cross-sectional view taken along line VIII-VIII′ in FIG. 6. A repeated description of the constituent elements substantially identical to the constituent elements illustrated in FIGS. 1 to 5 will be omitted or may be briefly provided. The same reference numerals are used for the same components.

With reference to FIGS. 1, 5, 6, and 7A together, in the display device 100 according to the embodiment of the present disclosure, the first power line PL1 is disposed in the non-display area NA between the display area AA and the bending area BA.

With reference to FIG. 8 together, the passivation layer 114 can be disposed to cover the first power line PL1.

With reference to FIGS. 6, 7B, and 8 together, the second power line PL2 partially connected to the first power line PL1 can be disposed on the passivation layer 114.

In the display device 100 according to the embodiment of the present disclosure, the second power line PL2 can be patterned so that an end thereof is disposed between the display area AA and the bending area BA. For example, the end of the second power line PL2 can overlap the first portion of the first dam DAM1. For example, the end of the second power line PL2 can overlap the second portion of the second dam DAM2.

With reference to FIGS. 1, 6, and 7C together, in the non-display area NA between the display area AA and the bending area BA, the first layer L1 of the first dam DAM1, which is disposed to surround the display area AA, and the first layer L1 of the second dam DAM2, which is positioned outward of the first dam DAM1, can be disposed on the first power line PL1.

The first layer L1 of the first dam DAM1 and the first layer L1 of the second dam DAM2 can be disposed on the same layer and made of the same material as the second planarization layer 115b. The first layer L1 of the first dam DAM1 and the first layer L1 of the second dam DAM2 can be spaced apart from the second planarization layer 115b extending from the display area AA.

In addition, a first organic pattern OP1 and a second organic pattern OP2 can be disposed on the second power line PL2 and cover the end of the second power line PL2. For example, the first organic pattern OP1 can be disposed to be closer to a central portion than the second organic pattern OP2 to the central portion.

The first organic pattern OP1 can connect the first layer L1 and the second planarization layer 115b extending from the display area AA. For example, the first organic pattern OP1 can be disposed on the same layer and made of the same material as the second planarization layer 115b and the first layer L1.

For example, the second organic pattern OP2 can be disposed between the first dam DAM1 and the second dam DAM2 and connect the first dam DAM1 and the second dam DAM2. For example, the second organic pattern OP2 can be disposed on the same layer and made of the same material as the second planarization layer 115b and the first layer L1.

For example, the first organic pattern OP1, the second organic pattern OP2, the second planarization layer 115b, the first layer L1 of the first dam DAM1, and the first layer L1 of the second dam DAM2 can be integrated by the first organic pattern OP1 and the second organic pattern OP2.

The first organic pattern OP1 and the second organic pattern OP2 cover the end of the second power line PL2, which can suppress or prevent the occurrence of seam at the end of the second power line PL2, thereby improving the reliability of the display device.

With reference to FIGS. 7D and 8 together, the third power line PL3, which is connected to the second power line PL2 and disposed along the first dam DAM1, can be disposed on the first layer L1 of the first dam DAM1 and the first organic pattern OP1 in the non-display area NA.

In the display device 100 according to the embodiment of the present disclosure, the third power line PL3 can extend along the first dam DAM1, such that the end of the third power line PL3 may not be disposed between the display area AA and the bending area BA.

The third power line PL3 can be disposed on the same layer as the first electrode E1. For example, the third power line PL3 can include a reflective layer, and a transparent conductive layer on the reflective layer. For example, the reflective layer can include silver (Ag).

With reference to FIG. 7E, the second layer L2 of each of the first dam DAM1 and the second dam DAM2 can be disposed to correspond to each of the first dam DAM1 and the second dam DAM2.

Specifically, the second layer L2 of the first dam DAM1 can be disposed on the third power line PL3 in the area corresponding to the first dam DAM1, and the second layer L2 of the second dam DAM2 can be disposed on the first layer L1 of the second dam DAM2 in the area corresponding to the second dam DAM2.

In this case, the second layer L2 of each of the first dam DAM1 and the second dam DAM2 can be disposed on the same layer as the bank 116a disposed in the display area AA and spaced apart from the bank 116a disposed in the display area AA. In addition, the second layers L2 of the first and second dams DAM1 and DAM2 can be spaced apart from each other.

With reference to FIG. 7F, the third layer L3 can be disposed on the second layer L2. In this case, the third layer L3 can be disposed on the same layer as the spacer 116b in the display area AA.

In the related art, one end of a third power line is positioned at a position overlapping a first organic pattern, and an organic layer is disposed on the first organic pattern and covers one end of the third power line to suppress the occurrence of seam of the third power line. Therefore, the organic layer, which is positioned on the same layer as the bank, is further disposed on an upper portion of the first organic pattern connecting a planarization layer and a first dam in a display area, such that a non-display area and the display area are connected by the organic layer on the third power line. Therefore, in case that a second dam cracks during a process of depositing an encapsulation layer, the crack formed in the second dam propagates to a first dam along the organic layer on an uppermost layer of a second organic pattern and propagates from the first dam to the display area along the organic layer on an uppermost layer of a first organic pattern, and foreign substances such as outside moisture or oxygen propagate to the display area in accordance with the propagation of the crack, which causes a problem in that the reliability of the display device deteriorates. In addition, because the organic layer is patterned to overlap the first organic pattern, silver (Ag) included in the third power line can scatter during the process of patterning the organic layer. In this case, there is a problem in that a dark spot occurs when the scattering silver (Ag) is seated in the display area.

Therefore, in the display device 100 according to the embodiment of the present disclosure, as illustrated in FIG. 8, the third power line PL3 is extended and disposed on an uppermost layer of the first organic pattern OP1 that connects the first dam DAM1 and the display area AA. Therefore, even though the second dam DAM2 cracks and the crack propagates to the first dam DAM1, the third power line PL3, instead of the organic layer, can be disposed on the uppermost layer of the first organic pattern OP1 that connects the first dam DAM1 and the display area AA. Therefore, it is possible to suppress or prevent the problem of the propagation of outside moisture or oxygen along the crack into the display area AA by blocking the propagation of the crack that propagates along the organic layer.

In addition, in the display device 100 according to the embodiment of the present disclosure, the third power line PL3 is disposed along the first dam DAM1 on the first dam DAM1 and the first organic pattern OP1, such that one end of the third power line PL3 may not be disposed between the display area AA and the bending area BA. Therefore, it is not necessary to cover one end of the third power line PL3 between the display area AA and the non-display area NA and pattern an organic layer on the first organic pattern OP1. Therefore, it is possible to suppress or prevent a problem of silver (Ag) residue which can be caused by organic layer patterning.

The example embodiments of the present disclosure can also be described as follows:

According to an aspect of the present disclosure, a display device include a substrate having a display area in which a plurality of pixels is defined, and a non-display area configured to surround the display area, a planarization layer disposed on the substrate in the display area, a first power line disposed on the substrate in the non-display area, a second power line disposed on the first power line and connected to the first power line in the non-display area, first and second dams disposed on the first power line in the non-display area, the first dam being configured to surround the display area, and the second dam being positioned outward of the first dam, a first organic pattern configured to connect the planarization layer and the first dam and disposed on the second power line, a second organic pattern configured to connect the first dam and the second dam and disposed on the second power line, and a third power line disposed on the planarization layer, the first dam, and the first organic pattern, connected to the second power line, and disposed along the first dam.

The substrate further comprises a bending area extending and bent from one side of the non-display area, the first dam comprises a first portion extending in a rectilinear direction between the display area and the bending area, and a second portion extending from the first portion in a curved direction, and an end of the second power line can overlap a first portion of the first dam between the first organic pattern and the second organic pattern.

The end of the second power line can overlap the first organic pattern and the second organic pattern.

The first organic pattern can be disposed to be closer to a central portion than the second organic pattern.

The second dam comprises a first portion extending in a rectilinear direction between the display area and the bending area, and a second portion extending from the first portion in a curved direction, and an end of the second power line can overlap the second portion of the second dam.

The third power line can be disposed along shapes of the first and second portions of the first dam.

The display device can further include a plurality of thin-film transistors disposed on the substrate, a plurality of light-emitting elements disposed on the plurality of thin-film transistors and the planarization layer and comprising a first electrode, a light-emitting layer on the first electrode, and a second electrode on the light-emitting layer, and a bank layer configured to cover an end of the first electrode, the third power line can be disposed on the same layer as the first electrode.

The first dam and the second dam each comprise a first layer made of the same material as the planarization layer, and a second layer made of the same material as the bank layer, and the planarization layer, the first organic pattern, the first layer of the first dam, the second organic pattern, and the first layer of the second dam can be integrated.

The bank layer and the second layer of the first dam can be spaced apart from each other.

The first electrode can include a reflective layer, and a transparent conductive layer on the reflective layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate having a display area in which a plurality of pixels is defined, and a non-display area configured to surround the display area;
a planarization layer disposed on the substrate in the display area;
a first power line disposed on the substrate in the non-display area;
a second power line disposed on the first power line and connected to the first power line in the non-display area;
a first dam and a second dam disposed on the first power line in the non-display area, the first dam being configured to surround the display area, and the second dam being positioned at an outer side of the first dam;
a first organic pattern configured to connect the planarization layer and the first dam and disposed on the second power line;
a second organic pattern configured to connect the first dam and the second dam and disposed on the second power line; and
a third power line disposed on the planarization layer, the first dam, and the first organic pattern,
wherein the third power line is connected to the second power line, and is disposed along the first dam.

2. The display device of claim 1, wherein the substrate further comprises a bending area extending and bent from one side of the non-display area,
wherein the first dam comprises:
a first portion extending in a rectilinear direction between the display area and the bending area; and
a second portion extending from the first portion in a curved direction, and
wherein an end of the second power line overlaps a first portion of the first dam between the first organic pattern and the second organic pattern.

3. The display device of claim 2, wherein the end of the second power line overlaps the first organic pattern and the second organic pattern.

4. The display device of claim 2, wherein the first organic pattern is disposed to be closer to a central portion than the second organic pattern.

5. The display device of claim 2, wherein the second dam comprises:
a first portion extending in the rectilinear direction between the display area and the bending area; and
a second portion extending from the first portion of the second dam in the curved direction, and
wherein an end of the second power line overlaps the second portion of the second dam.

6. The display device of claim 2, wherein the third power line is disposed along shapes of the first and second portions of the first dam.

7. The display device of claim 1, further comprising:
a plurality of thin-film transistors disposed on the substrate;
a plurality of light-emitting elements disposed on the plurality of thin-film transistors and the planarization layer, and comprising a first electrode, a light-emitting layer on the first electrode, and a second electrode on the light-emitting layer; and
a bank layer configured to cover an end of the first electrode,
wherein the third power line is disposed on a same layer as the first electrode.

8. The display device of claim 7, wherein each of the first dam and the second dam comprises:
a first layer made of a same material as the planarization layer; and
a second layer made of a same material as the bank layer, and
wherein the planarization layer, the first organic pattern, the first layer of the first dam, the second organic pattern, and the first layer of the second dam are integrated.

9. The display device of claim 8, wherein the bank layer and the second layer of the first dam are spaced apart from each other.

10. The display device of claim 8, wherein the first electrode comprises:
a reflective layer; and
a transparent conductive layer on the reflective layer.
